(19) United States
(12) Patent Application Publication
(10) Pub. No.: US 2024/0224745 A1
(43) Pub. Date: Jul. 4, 2024

(54) DISPLAY DEVICE

(71) Applicant: LG Display Co., Ltd., Seoul (KR)

(72) Inventors: Seungpyo HONG, Busan (KR); SeungHee NAM, Paju-si (KR); JungSun BAEK, Paju-si (KR)

(73) Assignee: LG Display Co., Ltd., Seoul (KR)

(21) Appl. No.: 18/510,333

(22) Filed: Nov. 15, 2023

(30) Foreign Application Priority Data
Dec. 30, 2022 (KR) 10-2022-0191298

(51) Int. Cl. H10K 59/80; H10K 59/126; H10K 59/35; H10K 59/38

(52) U.S. Cl. CPC H10K 59/878; H10K 59/126; H10K 59/35; H10K 59/38; H10K 59/8792

(57) ABSTRACT

A display device can include a light emitting layer; a transparent resin layer disposed on the light emitting layer and including an opening part corresponding to the light emitting layer, the opening part including an inclined side surface; a color converting layer disposed in the opening part; and a reflection plate positioned on the inclined side surface. Also, the color converting layer completely fills the opening part in the transparent resin layer.

### CROSS-REFERENCE TO RELATED APPLICATION

This application claims priority to Korean Patent Application No. 10-2022-0191298, filed in the Republic of Korea, on December 30, 2022, the entirety of which is hereby incorporated by reference into the present application for all purposes as if fully set forth herein.

### BACKGROUND

### Field of the Invention

Embodiments of the present disclosure relate to a display device.

### Description of Related Art

Display devices displaying various kinds of information on screens are useful in the information telecommunication technology era and take a role of transferring various kinds of information to users.

A display device can be requested to have superior display quality, a superior light emission effect, and the like. In addition, a display device is requested to maintain superior display quality even when an angle with which a user views a screen is changed. Generally, there are problems in that the luminance is decreased, color coordinates are changed, and the like in accordance with an increase in a viewing angle with which a display device is viewed in a side-face direction.

A display device includes a light emitting element that generates light, and in order for the light generated by the light emitting element to reach a user, the light needs to pass through various layers configuring the display device. However, in the process of light emitted from a light emitting element that passes through various layers configuring the display device, a part of the light is not extracted to the outside of the display device and remains confined inside the display device. Also, when a black matrix is used between subpixels in the display device to prevent color mixing, the processing steps for forming the black matrix can introduce problems and the black matrix can degenerate or impair other elements within the display device. Further, the black matrix can absorb light emitted from the subpixels, which can reduce luminance, impair image quality and increase power consumption. In order to improve efficiency of a display device, there exists a need for a configuration that maximally extracts light generated by a light emitting element.

### SUMMARY OF THE DISCLOSURE

A display device includes a color converting layer used for converting light generated by a light emitting element into different colors, and a black matrix can be positioned between color converting layers for preventing color mixing. However, there are problems in that efficiency of the display device is lowered due to absorption of light by the black matrix, and the processibility of the black matrix deteriorates. Thus, the inventors of this specification invented a display device that includes a transparent resin layer including an opening part and an inclined face, a color converting layer filling up the opening part, and a reflection plate positioned on the inclined face, which is capable of effectively extracting light, and has superior color characteristics even for wide viewing angles.

Embodiments of the present disclosure can provide a display device that includes a transparent resin layer including an opening part and an inclined face a color converting layer filling up the opening part and a reflection plate positioned on the inclined face, which is capable of effectively extracting light, and has superior color characteristics even for viewing angles.

Embodiments of the present disclosure can provide a display device including a light emitting layer, a transparent resin layer, a color converting layer, and a reflection plate.

The transparent resin layer can be positioned on the light emitting layer. The transparent resin layer can include an opening part and an inclined face. The opening part can correspond the light emitting layer. The inclined face can be positioned on the outskirt of the opening part. The color converting layer can fill up the opening part. The reflection plate can be positioned on the inclined face.

According to embodiments of the present disclosure, a display device that includes a transparent resin layer including an opening part and an inclined face, a color converting layer filling up the opening part, and a reflection plate positioned on the inclined face, is capable of effectively extracting light to have superior efficiency, and bas superior color characteristics even for wide viewing angles can be provided.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, which are briefly described below.

FIG. 1 is a system configuration diagram of a display device according to embodiments of the present disclosure.

FIG. 2 is a cross-sectional view of a display device according to embodiments of the present disclosure and a circuit diagram of a subpixel.

FIG. 3 is a cross-sectional view and a plan view of a display device according to an embodiment of the present disclosure.

FIG. 4 is a cross-sectional view and a plan view of a display device according to embodiments of the present disclosure.

FIG. 5 is a cross-sectional view of a display device according to embodiments of the present disclosure.

FIG. 6 is a cross-sectional view of subpixels of a display device according to embodiments of the present disclosure.

FIG. 7 is a cross-sectional view of a display device according to embodiments of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including.” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” can be used herein to describe elements of the present disclosure. Each of these terms is not used to define essence. order, sequence, or number of elements etc., but is used merely to distinguish the corresponding element from other elements.

When it is mentioned that a first element “is connected or coupled to,” “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element can be included in at least one of two or more elements that “are connected or coupled to,” “contact or overlap,” etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “can.”

The features of various embodiments of the present disclosure can be partially or entirely coupled to or combined with each other and can be interlocked and operated in technically various ways, and the embodiments can be carried out independently of or in association with each other.

Hereinafter, various embodiments of the present disclosure will be described in detail with reference to the attached drawings.

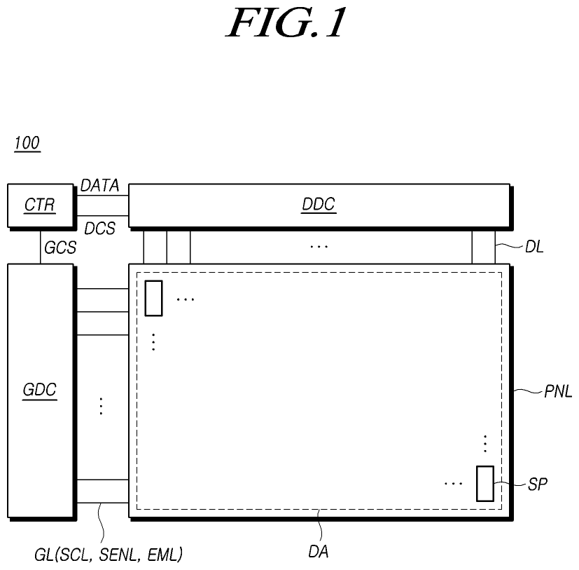

FIG. 1 is a system configuration diagram of an organic light emitting display device (100) according to embodiments of the present disclosure.

Referring to FIG. 1, the organic light emitting display device (100) according to the embodiments of the present disclosure can include a display panel (PNL) in which multiple data lines (DL) and multiple gate lines (GL) are disposed, and multiple subpixels (SP) connected to the multiple data lines (DL) and the multiple gate lines (GL) are arranged in an active area (AA) and driving circuits used for driving the display panel (PNL).

From a functional point of view, the driving circuit can include a data driving circuit (DDC) driving multiple data lines (DL), a gate driving circuit (GDC) driving multiple gate lines (GL), a controller (CTR) controlling the data driving circuit (DDC) and the gate driving circuit (GDC), and the like.

In the display panel (PNL), the multiple data lines (DL) and the multiple gate lines (GL) can intersect with each other. For example, the multiple data lines (DL) can be disposed in a row or a column, and the multiple gate lines (GL) can be disposed in a column or a row. Hereinafter, for the convenience of description, it is assumed that the multiple data lines (DL) are disposed in a row, and the multiple gate lines (GL) are disposed in a column.

The controller (CTR) supplies various control signals (DCS, GCS) required for driving operations of the data driving circuit (DDC) and the gate driving circuit (GDC) and controls the data driving circuit (DDC) and the gate driving circuit (GDC).

Such a controller (CTR) starts scanning in accordance with a timing implemented in each frame, converts input video data input from the outside into a data signal format used by the data driving circuit (DDC), outputs converted video data (DATA), and controls data driving at an appropriate time according to scanning.

Such a controller (CTR) can be a timing controller used in a general display technology or can be a control device that includes a timing controller and can further perform other control functions.

The controller (CTR) can be implemented using a component that is separate from the data driving circuit (DDC) or can be integrated with the data driving circuit (DDC) and implemented as an integrated circuit.

The data driving circuit (DDC) receives video data (DATA) from the controller (CTR) as an input and supplies data voltages to multiple data lines (DL), thereby driving the multiple data lines (DL). Here, the data driving circuit (DDC) is also referred to as a source driving circuit.

The data driving circuit (DDC) can be implemented to include at least one or more source driver integrated circuits (S-DIC). Each source driver integrated circuit (S-DIC) can include a shift register, a latch circuit, a digital to analog converter (DAC), an output buffer, and the like. In some situations, each source-driver integrated circuit (S-DIC) can further include an analog to digital converter (ADC).

Each source driver integrated circuit (S-DIC) can be connected to a bonding pad of the display panel (PNL) as a tape automated bonding (TAB) type or a chip on glass (COG) type or can be directly disposed on the display panel (PNL) or, in some situations, can be disposed to be integrated in the display panel (PNL). In addition, each source driver integrated circuit (S-DIC) can be implemented as a chip-on-film (COF) type in which the source driver integrated circuit (S-DIC) is mounted on a source-circuit film connected to the display panel (PNL).

The gate driving circuit (GDC) sequentially supplies scanning signals to multiple gate lines (GL), thereby sequentially driving the multiple gate lines (GL). Here, the gate driving circuit (GDC) can also be referred to as a scanning driving circuit.

The gate driving circuit (GDC) can be connected to the bonding pad of the display panel (PNL) as a tape automated bonding (TAB) type or a chip on glass (COG) type. can be implemented as a gate-in-panel (GIP) type and directly disposed in the display panel (PNL), or, in some situations, can be disposed with being integrated in the display panel (PNL). In addition, the gate driving circuit (GDC) can be implemented by multiple gate driver integrated circuits (G-DIC) and be implemented as a chip-on-film (COF) type in which it is mounted on a gate-circuit film connected to the display panel (PNL).

The gate driving circuit (GDC) sequentially supplies scanning signals of an on-voltage and an off-voltage to multiple gate lines (GL) in accordance with control of the controller (CTR).

When a specific gate line is opened by the gate driving circuit (GDC), the data driving circuit (DDC) converts video data (DATA) received from the controller (CTR) into data voltages of an analog form and supplies the data voltages to multiple data lines (DL).

The data driving circuit (DDC) can be positioned on one side (e.g., an upper side or a lower side) of the display panel (PNL) or can be positioned on both sides (e.g., the upper side and the lower side) of the display panel (PNL) in accordance with a driving type, a panel design type, and the like according to circumstances.

The gate driving circuit (GDC) can be positioned on one side (e.g., a left side or a right side) of the display panel (PNL) or can be positioned on both sides (e.g., the left side and the right side) of the display panel (PNL) in accordance with a driving type, a panel design type, and the like according to circumstances.

The multiple gate lines (GL) disposed in the display panel (PNL) can include multiple scanning lines (SCL), multiple sense lines (SCL), and multiple light emitting control lines (EML). The scanning lines (SCL), the sense lines (SCL), and the light emitting control lines (EML) are wirings transferring gates signals of mutually-different types (scanning signals. sense signals, and light emitting control signals) to gate nodes of transistors of mutually-different types (scanning transistors. sense transistors, and light emitting control transistors).

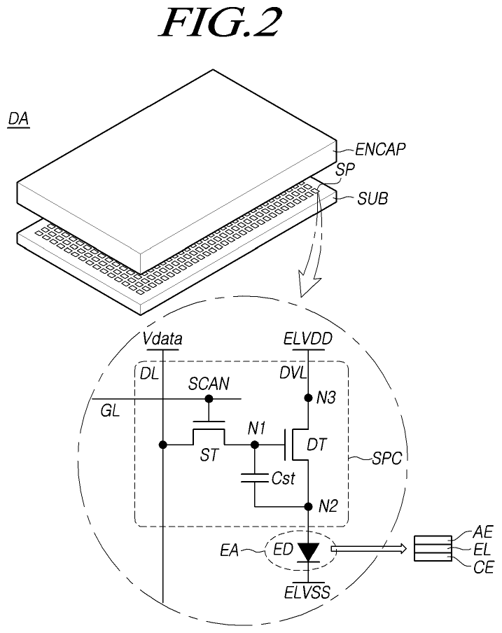

FIG. 2 is a schematic cross-sectional structure of a display device according to embodiments of the present disclosure and a circuit diagram of a subpixel.

Referring to FIG. 2, a plurality of subpixels (SP) can be disposed in a display area (DA).

Referring to FIG. 2, each of the plurality of subpixels (SP) can include a light emitting element (ED) and a subpixel circuit unit (SPC) configured for driving the light emitting element (ED).

Referring to FIG. 2, the subpixel circuit unit (SPC) can include a driving transistor (DT) used for driving a light emitting element (ED), a scanning transistor (ST) used for transferring a data voltage (Vdata) to a first node (N1) of the driving transistor (DT), a storage capacitor (Cst) used for maintaining a constant voltage for one frame, and the like.

The driving transistor (DT) can include a first node (N1) to which a data voltage can be applied, a second node (N2) electrically connected to the light emitting element (ED), and a third node (N3) to which a drive voltage (ELVDD) is applied from the drive voltage line (DVL). In the driving transistor (DT), the first node (N1) can be a gate node, the second node (N2) can be a source node or a drain node, and the third node (N3) can be a drain node or a source node. Hereinafter, for the convenience of description, a situation in which, in the driving transistor (DT), the first node (N1) is a gate node, the second node (N2) is a source node, and the third node (N3) is a drain node will be described as an example.

The light emitting element (ED) can include an anode electrode (AE), a light emitting layer (EL), and a cathode electrode (CE). The anode electrode (AE) can be a pixel electrode disposed in each subpixel (SP) and can be electrically connected to the second node (N2) of the driving transistor (DT) of each subpixel (SP). The cathode electrode (CE) can be a common electrode disposed to be common to a plurality of subpixels (SP) and can be applied with a ground voltage (ELVSS).

For example, the anode electrode (AE) can be a pixel electrode, and the cathode electrode (CE) can be a common electrode. To the contrary, the anode electrode (AE) can be a common node, and the cathode electrode (CE) can be a pixel electrode. Hereinafter, for the convenience of description, it is assumed that the anode electrode (AE) is a pixel electrode, and the cathode electrode (CE) is a common electrode.

The light emitting element (ED) can have a predetermined light emitting area (EA), and the light emitting area (EA) of the light emitting element (ED) can be defined as an area in which the anode electrode (AE), the light emitting layer (EL). and the cathode electrode (CE) overlap with each other.

For example, the light emitting element (ED) can be an organic light emitting diode (OLED), an inorganic light emitting diode (LED), a quantum dot light emitting element, or the like. In a situation in which the light emitting element (ED) is an organic light emitting diode, the light emitting layer (EL) of the light emitting element (ED) can include an organic light emitting layer (EL) in which an organic material is contained.

The scanning transistor (ST) is controlled to be on or off in accordance with a scanning signal (SCAN) that is a gate signal applied through the gate line (GL) and can be electrically connected between the first node (N1) of the driving transistor (DT) and the data line (DL).

The storage capacitor (Cst) can be electrically connected between the first node (N1) and the second node (N2) of the driving transistor (DT).

As illustrated in FIG. 2, the subpixel circuit unit (SPC) can have a 2T (transistor) 1C (capacitor) structure including two transistors (DT, ST) and one capacitor (Cst) and, in some situations, can further include one or more transistors or one or more capacitors.

The storage capacitor (Cst) may not be just a parasitic capacitor (e.g., Cgs or Cgd) that is an internal capacitor present between the first node (N1) and the second node (N2) of the driving transistor (DT), but can be an external capacitor that is intentionally designed outside the driving transistor (DT). Each of the driving transistor (DT) and the scanning transistor (ST) can be either an n-type transistor or a p-type transistor.

Circuit elements (particularly, a light emitting element (ED) implemented as an organic light emitting diode (OLED) containing organic materials) inside each subpixel (SP) are weak to external moisture, oxygen, and the like, and thus an encapsulation layer (ENCAP) for preventing penetration of external moisture or external oxygen to penetrate into circuit elements (particularly, the light emitting element (ED)) can be disposed. The encapsulation layer (ENCAP) can be disposed in a form covering the light emitting elements (ED).

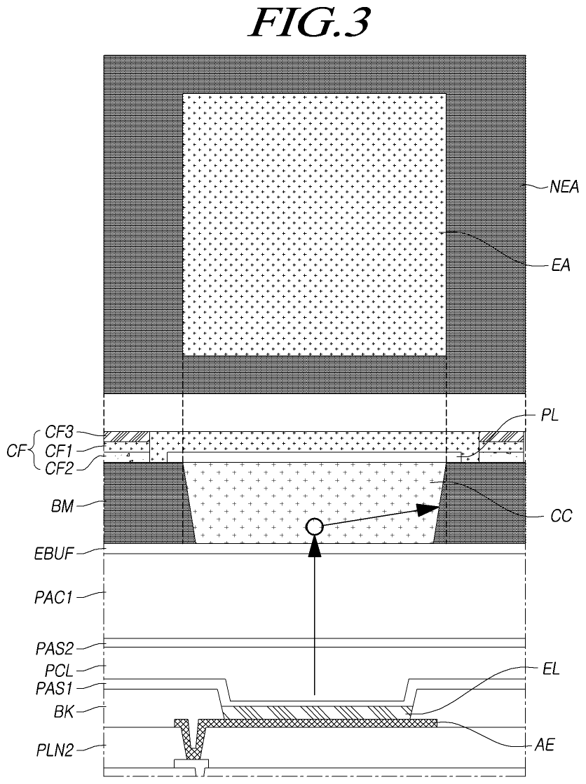

FIG. 3 is a cross-sectional view and a plan view of a display device according to a comparative example of the present disclosure.

Referring to FIG. 3, the display device can include a second planarization layer (PLN2), an anode electrode (AE), a bank (BK), a light emitting layer (EL), a first passivation layer (PAS1), a first organic encapsulation layer (PCL), a second passivation layer (PAS2), a second organic encapsulation layer (PAC1), a third buffer layer (EBUF), a black matrix (BM), a color converting layer (CC), a protection layer (PL), and a color filter (CF).

Light emitted from the light emitting layer (EL) can reach the color converting layer (CC). The color converting layer (CC) can be a layer that converts a wavelength of the light emitted from the light emitting layer (EL) into a different wavelength. For example, the color converting layer (CC) can be a layer that converts light into a first color. The color converting layer (CC), for example, can be a resin layer containing particles or pigments that are able to convert the color. For example, the color converting layer (CC) can include quantum dots that are able to convert the color.

A part of the light that has reached the color converting layer (CC) has its color changed in accordance with particles, pigments, or the like contained in the color converting layer (CC) and can advance toward the black matrix (BM).

The black matrix (BM) can be positioned between the color converting layer (CC) and another color converting layer adjacent thereto. For example, the black matrix (BM) can be disposed between two color converting layers of two adjacent subpixels. The black matrix (BM) is positioned between color converting layers converting light into different colors, thereby being able to prevent light displayed by subpixels corresponding to mutually-different colors from mixing or interfering with each other. In addition, the black matrix (BM) inhibits reflection of external light that has reached the display device and can improve visibility of the display device. In order to effectively perform the roles described above, the black matrix (BM) can contain pigments or particles that can realize a black color. However, in a situation in which a content of pigments or particles is raised for realizing a black color, there is a problem in that the processibility of the black matrix (BM) is remarkably degraded or becomes impaired.

The display device can include a light emitting area (EA) and a non-light emitting area (NEA). The light emitting area (EA) can be positioned in correspondence with an opening part of the black matrix (BM). For example, a center of and opening part of the black matrix (BM) can be aligned and overlap with a center of the light emitting area (EA) of a subpixel.

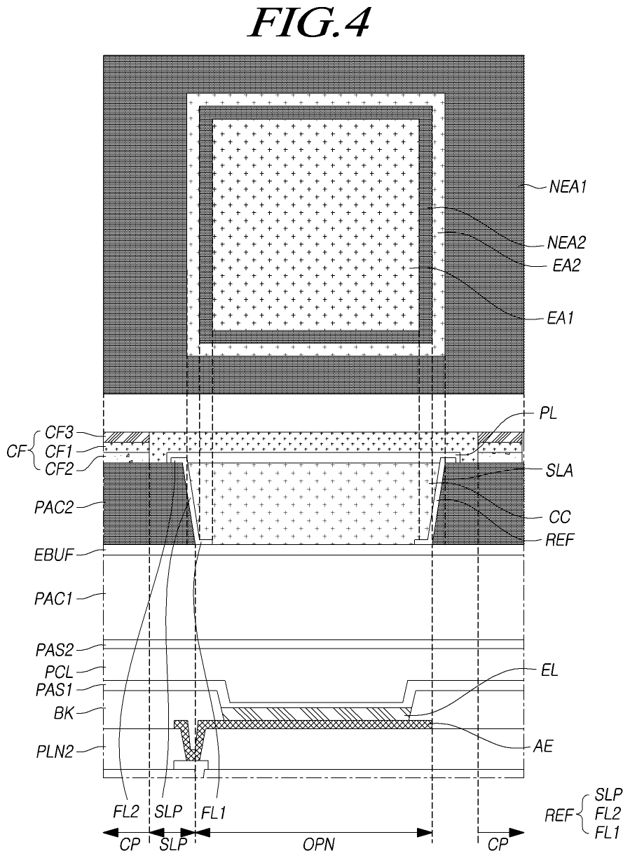

FIG. 4 is a cross-sectional view and a plan view of a display device according to embodiments of the present disclosure. In describing matters of the display device according to the embodiments of the present disclosure illustrated in FIG. 4, the matters thereof can be the same as those corresponding to the display device according to the comparative example illustrated in FIG. 3 unless otherwise mentioned.

Referring to FIG. 4, the display device can include a light emitting layer (EL), a transparent resin layer (PAC2), a color converting layer (CC1), and a reflection plate (REF).

The light emitting layer (EL) is a layer configuring a light emitting element of the display device and can be positioned between an anode electrode (AE) and a cathode electrode.

The transparent resin layer (PAC2) is a layer positioned between color converting layers (CC) and can include an opening part (OPN) corresponding to the light emitting layer (EL). In addition, the transparent resin layer (PAC2) can include an inclined face (SLA) positioned on the outskirt of the opening part (OPN). For example, the inclined face (SLA) can also be referred to as an inclined side surface of the opening part (OPN).

The inclined face (SLA) can have an angle such that a width of the opening part of the transparent resin layer (PAC2) increase as the opening part is further away from the light emitting layer (EL). In other words, the inclined face (SLA) can have a reverse tapered shape relative to the substrate (SUB).

Different from the display device according to the comparative example illustrated in the embodiment of FIG. 3 including the black matrix (BM), the display device according to the embodiments of the present disclosure can include a transparent resin layer (PAC2) that is different form the black matrix (BM). In a situation in which the display device includes the transparent resin layer (PAC2), pigments, particles, or the like for realizing a black color in the transparent resin layer (PAC2) may not be added, and the transparent resin layer (PAC2) is optically transparent, and thus a patterning process using electromagnetic waves such as ultraviolet rays can be easily performed. In other words, the transparent resin layer (PAC2) is not black, rather it is transparent and configured to allow light to pass through it. Accordingly, problems that may occur when manufacturing the black matrix (BM) can be avoided altogether when using the transparent resin layer (PAC2), since the black matrix (BM) is not included in this situation.

The reflection plate (REF) can be positioned on the inclined face (SLA). In a situation in which the reflection plate (REF) is positioned on the inclined face (SLA), light directed in a side-face direction other than the display area of the display device can be extracted to the outside of the display device through reflection. In addition, by causing light of which a color has not been converted in the color converting layer (CC) to pass through the color converting layer (CC) again, the color conversion efficiency can be further increased. In other words, instead of losing or trapping the light that would have been absorbed and blocked by the black matrix (BM) in the configuration of FIG. 3, the configuration show in FIG. 4 including the transparent resin layer (PAC2) with the reflection plate (REF) positioned on the inclined face (SLA) can be used to reflect this type of light to the outside towards a viewer, which can improve the light extraction, brightness and viewing angle.

The reflection plate (REF) can include a first planarization part (FL1), a second planarization part (FL2), and an inclined part (SLP). The inclined part (SLP) of the reflection plate (REF) can correspond to the inclined face (SLA) of the transparent resin layer (PAC2) and both can have a same angle, but embodiments are not limited thereto and the inclined part (SLP) and the inclined face (SLA) can have different slopes from each other.

The first planarization part (FL1) can be positioned inside an opening part (OPN). The first planarization part (FL1) being positioned inside the opening part (OPN) can represent that the first planarization part (FL1) not being positioned on the transparent resin layer (PAC2). In addition, the first planarization part (FL1) can be a part that extends from an inclined part (SLP) of the reflection plate (REF) to an inner side of the opening part (OPN).

The second planarization part (FL2) can be positioned on the outskirt of the opening part (OPN) The second planarization part (FL2) being positioned on the outskirt of the opening part (OPN) can represent that the second planarization part (FL2) is positioned on the outskirt of the inclined face (SLA) of the transparent resin layer (PAC2). In addition, the second planarization part (FL2) can be a part that extends from an inclined part (SLP) of the reflection plate (REF) to a flat part of the transparent resin layer (PAC2). For example, the second planarization part (FL2) of the reflection plate (REF) can overlap with an upper edge of transparent resin layer (PAC2).

The inclined part (SLP) can connect the first planarization part (FL1) and the second planarization part (FL2) to each other. The inclined part (SLP) connecting the first planarization part (FL1) and the second planarization part (FL2) to each other can represent that the inclined part (SLP) is positioned between the first planarization part (FL1) and the second planarization part (FL2). Also, the reflection plate (REF) can have a ring shape or a closed loop shape that surrounds the color converting layer (CC) that is in the opening part (OPN) of the transparent resin layer (PAC2).

The display device can include a first light emitting area (EA1), a second light emitting area (EA2), a first non-light emitting area (NEA1), and a second non-light emitting area (NEA2). For example, the second non-light emitting area (NEA2) can correspond to the first planarization part (FL1) of the reflection plate (REF), and the inclined part (SLP) of the reflection plate (REF) can correspond to the second light emitting area (EA2).

The first light emitting area (EA1) is a main light emitting area of a subpixel and can be positioned in correspondence with the light emitting layer (EL). In addition, the first light emitting area (EA1) can be positioned in correspondence with the opening part (OPN) of the transparent resin layer (PAC2).

The second light emitting area (EA2) can be positioned on the outskirt of the first light emitting area (EA1). The second light emitting area (EA2) can be positioned to be separate from the first light emitting area (EA1). The second light emitting area (EA2) being positioned to be separate from the first light emitting area (EA1) can represent that the second light emitting area (EA2) is positioned to be substantially completely separate from the first light emitting area (EA1).

The second light emitting area (EA2) can be positioned in correspondence with the inclined part (SLP). For example, the reflection plate (REF) can be a type of side mirror that is configured to output the light that creates the second light emitting area (EA2). The second light emitting area (EA2) being positioned in correspondence with the inclined part (SLP) represents that the second light emitting area (EA2) is positioned to overlap with or coincide with the inclined part (SLP), or light emitted from the second light emitting area (EA2) is light reflected on the inclined part (SLP).

The second non-light emitting area (NEA2) can be positioned in correspondence with the first planarization part (FL1). The second non-light emitting area (NEA2) being positioned in correspondence with the first planarization part (FL1) can represent that the second non-light emitting area (NEA2) is positioned to overlap with or coincide with the first planarization part (FL1). Also, the second non-light emitting area (NEA2) can have a ring shape or a closed loop shape that surrounds the first light emitting area (EA1), and the second light emitting area (EA2) can have a ring shape or a closed loop shape that surrounds the second non-light emitting area (NEA2).

The second non-light emitting area (NEA2) can be positioned between the first light emitting area (EA1) and the second light emitting area (EA2). The first non-light emitting area (NEA1) can be positioned on the outskirt of the second light emitting area (EA2).

The display device can include a first color filter (CF1) positioned on the color converting layer (CC). For example, the color converting layer (CC) can be disposed between the light emitting layer (EL) for a subpixel and the first color filter (CF1). In such an example, the light emitting layer (EL) can emit light having a third color, the color converting layer (CC) can convert the third color into a first color, and the first color filter (CF1) can pass all or a part of the light having the first color in order to further improve the color quality of the emitted light (e.g., providing colors that are more pure, such as greener greens, bluer blues and reds that are more red, etc.). In other words, the color converting layer (CC) and the first color filter (CF1) can be in correspondence with the same first color. In a situation in which the first color filter (CF1) is positioned on the color converting layer (CC), the display device can have far superior color characteristics.

The display device can include a first color filter (CF1) positioned on the transparent resin layer (PAC2), a second color filter (CF2) positioned on the transparent resin layer (PAC2), and a third color filter (CF3) positioned on the transparent resin layer (PAC2). In such an example, the display device can include a color mixing preventing area (CP) in which the first color filter (CF1), the second color filter (CF2), and the third color filter (CF3) are stacked on the outskirt of the reflection plate (REF). For example, the color mixing preventing area (CP) is made up of overlapping color filter portions and can function similar to a black matrix for preventing color mixing between adjacent subpixels. The color mixing preventing area (CP) is an area positioned between subpixels corresponding light of mutually-different colors and can represent an area in which the first color filter (CF1), the second color filter (CF2), and the third color filter (CF3) are positioned to overlap with each other. In such an example, the first color filter (CF1) can pass light having the first color, the second color filter (CF2) can pass light having the second color, and the third color filter (CF3) can pass light having the third color. In such an example, the first color can be a red color, the second color can be a green color, and the third color can be a blue color. In a situation in which the display device includes the color mixing preventing area (CP) described above. the display device can have far superior color characteristics.

The color mixing preventing area (CP) can be positioned to be separate from the reflection plate (REF) In accordance with the color mixing preventing area (CP) being positioned to be separate from the reflection plate (REF), a processing margin for being able to position the first color filter (CF1) corresponding to the first light emitting area (EA1) and the light emitting layer (EL) can be secured.

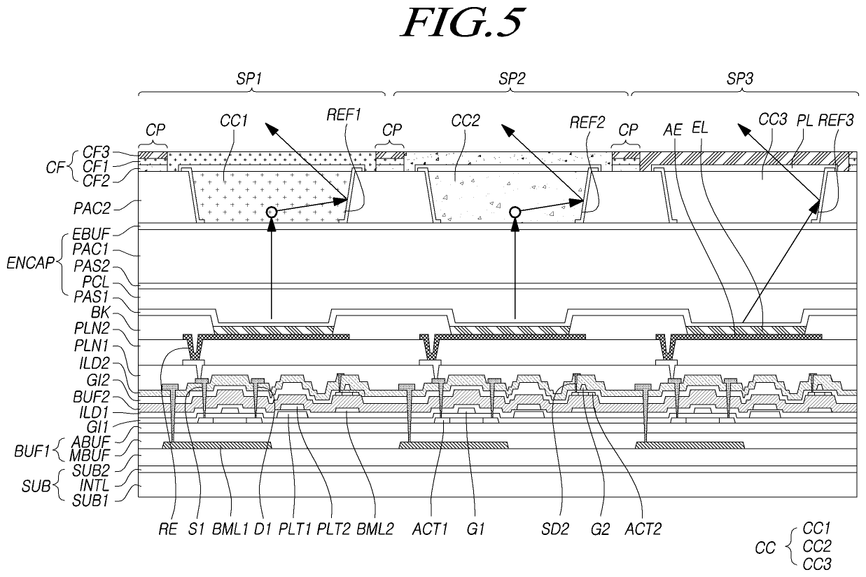

FIG. 5 is a cross-sectional view of a display device according to embodiments of the present disclosure.

Referring to FIG. 5, the display device can include a first subpixel (SP1), a second subpixel (SP2), and a third subpixel (SP3). The first subpixel (SP1) can emit red light and include a first reflection plate (REF1). The second subpixel (SP2) can emit green light and include a second reflection plate (REF2). The third subpixel (SP3) can emit blue light and include a third reflection plate (REF3). Matters relating to the first reflection plate (REF1), the second reflection plate (REF2), and the third reflection plate (REF3) can be the same as those of the reflection plate (REF) described above with reference to FIG. 4 unless otherwise mentioned.

The display device can include a substrate (SUB). The substrate (SUB) can include a first substrate (SUB1), an intermediate layer (INTL), and a second substrate (SUB2).

The display device can include a first buffer layer (BUF1) positioned on the substrate (SUB). The first buffer layer (BUF1) can include a multi-buffer layer (MBUF) and an active buffer layer (ABUF).

A first active layer (ACT1) can be positioned on the active buffer layer (ABUF). A first gate insulating film (GI1) can be positioned on the first active layer (ACTI). A first interlayer insulating film (ILD1) can be positioned on the first gate insulating film (GI1). A second buffer layer (BUF2) can be positioned on the first interlayer insulating film (ILD1). A second gate insulating film (GI2) can be positioned on the second buffer layer (BUF2) A second interlayer insulating film (ILD2) can be positioned on the second gate insulating film (GI2). A first planarization layer (PLN1) can be positioned on the second interlayer insulating film (ILD2). A second planarization layer (PLN2) can be positioned on the first planarization layer (PLN1). A bank (BK) can be positioned on the second planarization layer. An encapsulation layer (ENCAP) can be positioned on the bank (BK). The encapsulation layer (ENCAP) can include a first passivation layer (PAS1), a first organic encapsulation layer (PCL), a second passivation layer (PAS2), a second organic encapsulation layer (PAC1), and a third buffer layer (EBUF).

The display device can include various metal layers and circuit elements.

A first lower metal layer (BML1) can be positioned on the multi-buffer layer (MBUF). The first lower metal layer (BML1) can be positioned to overlap with the first transistor (TR1) or can be positioned below the first transistor (TR1). Also, the first color filter (CF1), the color converting layer (CC) and the light emitting layer (EL) for a subpixel can be aligned with and overlapping with the first transistor (TR1), which can save space and reduce reflections. improve image quality, and the first transistor (TR1) can be disposed between the subpixel and the first lower metal layer (BML1).

The first transistor (TR1) can include a first source electrode (S1), a first drain electrode (D1), a first gate electrode (G1), and a first active layer (ACT1).

A second transistor (TR2) can include a second source-drain electrode (SD2), a second gate electrode (G2), and a second active layer (ACT2).

The capacitor (Cst) can include a first plate (PLT1) and a second plate (PLT2).

The light emitting layer (EL) can be positioned in the first subpixel (SP1), the second subpixel (SP2), and the third subpixel (SP3). The light emitting layer (EL) can emit blue light.

The color converting layer (CC) can include a first color converting layer (CC1), a second color converting layer (CC2), and a third color converting layer (CC3).

The first color converting layer (CC1) can convert blue light emitted from the light emitting layer (EL) into red light. The first color converting layer (CC1) can include quantum dots that are able to convert blue light into red light. For example, the first color converting layer (CC1) can be a transparent resin layer that includes quantum dots.

The second color converting layer (CC2) can convert blue light emitted from the light emitting layer (EL) into green light. The second color converting layer (CC2) can include quantum dots that are able to convert blue light into green light. For example, the second color converting layer (CC2) can be a transparent resin layer that includes quantum dots.

The blue light emitted from the light emitting layer (EL) can pass through the third color converting layer (CC3) without being converted into a different color. Differently from the first color converting layer (CC1) and the second color converting layer (CC2), the third color converting layer (CC3) can be a transparent resin layer not including quantum dots.

Each of the first reflection plate (REF1), the second reflection plate (REF2), and the third reflection plate (REF3) can include a first planarization part (FL1), a second planarization part (FL2), and an inclined part (SLP).

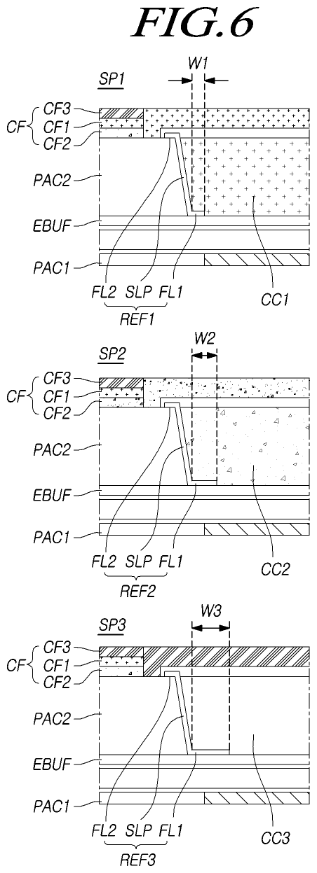

FIG. 6 is a cross-sectional view of subpixels of a display device according to embodiments of the present disclosure. More specifically, FIG. 6 is a cross-sectional view of a first subpixel (SP1), a second subpixel (SP2), and a third subpixel (SP3). Matters relating to the display device illustrated in FIG. 6 can be the same as those of the display device described above with reference to FIG. 5 unless otherwise mentioned.

Referring to FIG. 6, a first reflection plate (REF1), a second reflection plate (REF2), and a third reflection plate (REF3) can have shapes and sizes that are different from each other. In a situation in which the first reflection plate (REF1), the second reflection plate (REF2), and the third reflection plate (REF3) have shapes different from each other, the first reflection plate (REF1), the second reflection plate (REF2), and the third reflection plate (REF3) correspond to subpixels and light emitting elements displaying light of mutually-different colors, and thus visual angle characteristics of the light emitting elements having mutually-different visual angle characteristics are effectively corrected or compensated for, and the display device can have superior visual angle characteristics and each color can be finely tuned or adjusted via the sizing and shape of the corresponding reflection plate.

More specifically, a width (W2) of the first planarization part (FL1) of the second reflection plate (REF2) can be larger than a width (W1) of the first planarization part (FL1) of the first reflection plate (REF1) (e.g., W2>W1), and a width (W3) of the first planarization part (FL1) of the third reflection plate (REF3) can be larger than the width (W2) of the first planarization part (FL1) of the second reflection plate (REF2) (e.g., W3>W2). In a situation in which the widths of the first planarization parts (FL1) of the reflection plates (REF1, REF2. REF3) of subpixels emitting light of a shorter wavelength are configured to be long, color coordinates of the display device can be inhibited from deviating in a complementary color direction of the light of the short wavelength described above at a side-face viewing angle direction. For example, in a situation in which the third subpixel (SP3) displays blue light, when the width (W3) of the first planarization part (FL1) of the third reflection plate (REF3) is configured to be the longest, a problem of a screen displayed by the display device becoming yellowish at the side-face viewing angle direction can be prevented. For example, by using different sizes and shapes for the reflection plates of different colors, a color shift problem can be prevented from occurring even for wide viewing angles and truer or more pure colors can be provided, which improves image quality.

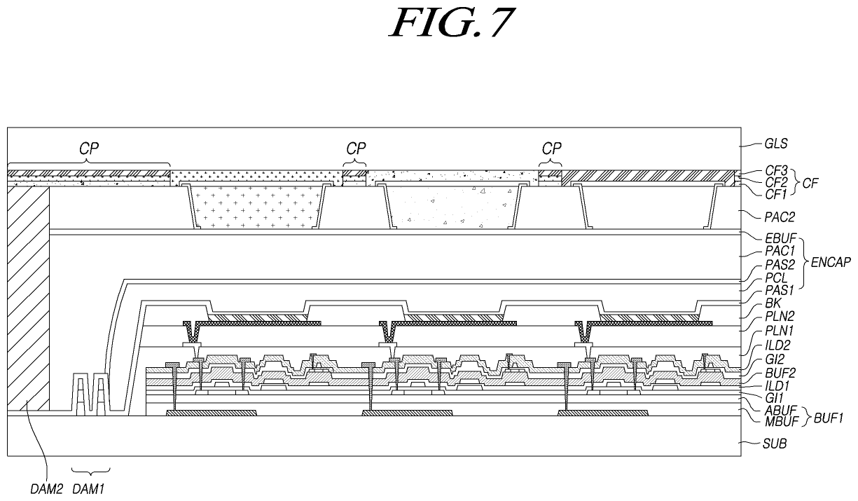

FIG. 7 is a cross-sectional view of a display device according to embodiments of the present disclosure.

As described above with reference to FIGS. 1, 2, and 4, the display device according to the embodiments of the present disclosure can include a display area in which a plurality of subpixels are positioned and a non-display area positioned on the outskirt of the display area. Referring to FIG. 7, the display device can include dams (DAM1, DAM2) positioned in the non-display area. The color mixing preventing area (CP) can be positioned to overlap with the dams (DAM1, DAM2)

The display device can encapsule the light emitting elements in a so-called Dam & Fill type. The display device can include a first dam (DAM1) positioned on the outskirt of the first organic encapsulation layer (PCL) and a second dam (DAM2) positioned on the outskirt of the second organic encapsulation layer (PAC1). The second dam (DAM2) can be positioned on the outskirt of the transparent resin layer (PAC2). In addition, the display device can include a cover glass (GLS) positioned on the color filter (CF)

The color mixing preventing area (CP) can be positioned in the non-display area. In addition, the color mixing preventing area (CP) can be positioned to overlap with the first dam (DAM1). In addition, the color mixing preventing area (CP) can be positioned to overlap with the second dam (DAM2).

In a situation in which the color mixing preventing area (CP) is positioned to overlap with the dam (DAM1, DAM2), the display device is inhibited from reflecting external light, and the display device can have superior visibility. For example, reflections off of the dam (DAM1, DAM2) can be prevented or blocked from a viewer.

The embodiments of the present disclosure described above can be briefly described as below.

A display device (100) can include a light emitting layer (EL), a transparent resin layer (PAC2), a color converting layer (CC), and a reflection plate (REF). The transparent resin layer (PAC2) can include an opening part (OPN) corresponding to the light emitting layer (EL) and an inclined face (SLA) positioned on the outskirt of the opening part (OPN). The color converting layer (CC) can fill up the opening part (OPN). The reflection plate (REF) can be positioned on the inclined face (SLA).

The inclined face (SLA) can have a tapered shape or a sloped shape.

The reflection plate (REF) can include a first planarization part (FL1), a second planarization part (FL2), and an inclined part (SLP). The first planarization part (FL1) can be positioned inside the opening part (OPN). The second planarization part (FL2) can be positioned on the outskirt of the opening part (OPN). The inclined part (SLP) can connect the first planarization part (FL1) with the second planarization part (FL2) and be positioned on the inclined face (SLA).

The display device (100) can include a first light emitting area (EA1), a second light emitting area (EA2), a first non-light emitting area (NEA1), and a second non-light emitting area (NEA2). The second light emitting area (EA2) can be positioned on the outskirt of the first light emitting area (EA1) and positioned to be separate from the first light emitting area (EA1). The second non-light emitting area (NEA2) can be positioned between the first light emitting area (EA1) and the second light emitting area (EA2). The first non-light emitting area (NEA1) can be positioned on the outskirt of the second light emitting area (EA2).

The second light emitting area (EA2) can be positioned in correspondence with the inclined part (SLP). The second non-light emitting area (NEA2) can be positioned in correspondence with the first planarization part (FL1).

The display device (100) can include a first color filter (CF1) positioned on the color converting layer (CC).

The display device (100) can further include a first color filter (CF1) positioned on the transparent resin layer (PAC2), a second color filter (CF2) positioned on the transparent resin layer (PAC2), a third color filter (CF3) positioned on the transparent resin layer (PAC2), and a color mixing preventing area (CP). The color mixing preventing area (CP) can be an area in which the first color filter (CF1), the second color filter (CF2), and the third color filter (CF3) are stacked on the outskirt of the reflection plate (REF). The color mixing preventing area (CP) can be positioned to be separate from or spaced apart from the reflection plate (REF).

The display device (100) can include a first subpixel (SP1), a second subpixel (SP2), and a third subpixel (SP3). The first subpixel (SP1) can emit red light and include a first reflection plate (REF1). The second subpixel (SP2) can emit green light and include a second reflection plate (REF2). The third subpixel (SP3) can emit blue light and include a third reflection plate (REF3). The first reflection plate (REF1), the second reflection plate (REF2), and the third reflection plate (REF3) can respectively include a first planarization part (FL1), a second planarization part (FL2), and an inclined part (SLP). A width (W2) of the first planarization part (FL1) of the second reflection plate (REF2) can be larger than a width (W1) of the first planarization part (FL1) of the first reflection plate (REF1). A width (W3) of the first planarization part (FL1) of the third reflection plate (REF3) can be larger than the width (W2) of the first planarization part (FL1) of the second reflection plate (REF2).

The display device (100) can include a display area (DA) in which a plurality of subpixels (SP) are positioned, a non-display area (NDA) positioned on the outskirt of the display area (DA), and a dam (DAM1, DAM2) positioned in the non-display area (NDA). The color mixing preventing area (CP) can be positioned to overlap with the dam (DAM1, DAM2).

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a light emitting layer;
a transparent resin layer disposed on the light emitting layer and including an opening part corresponding to the light emitting layer, the opening part including an inclined side surface;
a color converting layer disposed in the opening part; and
a reflection plate positioned on the inclined side surface.

2. The display device according to claim 1, wherein the reflection plate has a closed loop shape surrounding the color converting layer disposed in the opening part of the transparent resin layer.

3. The display device according to claim 1, wherein the reflection plate includes:
a first planarization part disposed inside the opening part in the transparent resin layer;
a second planarization part disposed adjacent to the opening part in the transparent resin layer; and
an inclined part connecting the first planarization part with the second planarization part, the inclined part being disposed on the inclined side surface of the opening part in the transparent resin layer.

4. The display device according to claim 3, comprising:
a first light emitting area;
a second light emitting area spaced apart from the first light emitting area;
a second non-light emitting area between the first light emitting area and the second light emitting area; and
a first non-light emitting area outside of the second light emitting area.

5. The display device according to claim 4, wherein the second light emitting area corresponds with the inclined part of the reflection plate, and
wherein the second non-light emitting area corresponds with the first planarization part of the reflection plate.

6. The display device according to claim 4, wherein the second non-light emitting area has a first closed loop shape surrounding the first light emitting area, and the second light emitting has a second closed loop shape surrounding the second non-light emitting area.

7. The display device according to claim 1, further comprising a first color filter disposed on the color converting layer.

8. The display device according to claim 1, further comprising:
a first color filter disposed on the transparent resin layer;
a second color filter disposed on the transparent resin layer;
a third color filter disposed on the transparent resin layer; and
a color mixing preventing area including a first portion of the first color filter, a second portion of the second color filter, and a third portion of the third color filter, the first, second and third portions overlapping with each other,
wherein the color mixing preventing area does not overlap with the reflection plate and does not overlap with the opening part in the transparent resin layer.

9. The display device according to claim 1, further comprising:
a first subpixel configured to emit a first color light, the first subpixel including a first reflection plate;
a second subpixel configured to emit a second color light, the second subpixel including a second reflection plate; and
a third subpixel configured to emit a third color light, the third subpixel including a third reflection plate,
wherein the first reflection plate, the second reflection plate, and the third reflection plate respectively include a first planarization part, a second planarization part, and an inclined part,
wherein a width of the first planarization part of the second reflection plate is larger than a width of the first planarization part of the first reflection plate, and
wherein a width of the first planarization part of the third reflection plate is larger than the width of the first planarization part of the second reflection plate.

10. A display device comprising:
a subpixel disposed on a substrate, the subpixel including a light emitting part;
a transparent layer including a hole overlapping with the light emitting part of the subpixel;
a color converting part disposed in the hole in the transparent layer; and
a reflection plate disposed in the hole, the reflection plate being positioned between the color converting part and transparent layer.

11. The display device according to claim 10, wherein the color converting part is configured to covert a first color of light emitted from the light emitting part into a second color of light different than the first color.

12. The display device according to claim 10, wherein the reflection plate is configured to reflect the second color of light out of the display device.

13. The display device according to claim 10, wherein the reflection plate is disposed on an inclined side surface of the transparent layer.

14. The display device according to claim 10, wherein the reflection plate includes:
a first planarization part disposed inside the hole in the transparent layer;
a second planarization part disposed on the transparent layer in an area adjacent to the hole; and
an inclined part connected between the first planarization part with the second planarization part.

15. The display device according to claim 14, wherein the subpixel includes a first emission area, a second emission area, and a first non-emission area between the first emission area and the second emission area.

16. The display device according to claim 15, wherein the first non-emission area has a first closed loop shape surrounding the first emission area, and
wherein the second emission area has a second closed loop shape surrounding the first non-emission area.

17. The display device according to claim 15, wherein the first planarization part of the reflection plate overlaps with the first non-emission area, and
wherein the inclined part of the reflection plate overlaps with the second emission area.

18. The display device according to claim 10, further comprising a color filter disposed on the subpixel,
wherein the color converting part is disposed between the color filter and the light emitting part of the subpixel.

19. A display device, comprising:
a plurality of subpixels disposed on a substrate, each of the plurality of subpixels including a first emission area, a second emission area, and a first non-emission area between the first emission area and the second emission area; and
a light blocking layer including a plurality of openings corresponding to the plurality of subpixels,
wherein the first emission area, the first non-emission area and the second emission area of a corresponding subpixel among the plurality of subpixels is located inside of an opening among the plurality of openings in the light blocking layer.

20. The display device according to claim 19, wherein the light blocking layer includes two or more overlapping color filter layers.

21. The display device according to claim 19, further comprising:
a first layer including a hole corresponding to one of the plurality of subpixels; and
a color converting part disposed in the hole in the first layer.

22. The display device according to claim 21, further comprising:
a reflection plate disposed in the hole in the first layer, the reflection plate being positioned between the color converting part and the first layer.

23. The display device according to claim 21, wherein a size of the hole in the first layer is smaller than a size of each of plurality of openings in the light blocking layer.

24. The display device according to claim 21, further comprising:
a color filter layer disposed in at least one opening among the plurality of openings in the light blocking layer; and
a protection layer disposed in the at least one opening among the plurality of openings in the light blocking layer,
wherein the protection layer is disposed between the color filter layer and the first emission area.

25. The display device according to claim 21, further comprising:
a buffer layer disposed between the color converting part and the first emission area,
wherein the color converting part directly contacts an upper surface of the buffer layer.

26. The display device according to claim 19, wherein the light blocking layer includes two or more overlapping color filter layers in a bezel area outside of the plurality of subpixels.

27. The display device according to claim 26, further comprising: at least one dam disposed in the bezel area,
wherein at least a portion of the two or more overlapping color filter layers in the bezel area overlaps with the at least one dam.

28. The display device according to claim 19, further comprising:
a first color filter layer disposed in a first opening among the plurality of openings in the light blocking layer corresponding to a first subpixel among the plurality of subpixels;
a second color filter layer disposed in a second opening among the plurality of openings in the light blocking layer corresponding to a second subpixel among the plurality of subpixels;
a first layer including a first hole corresponding to the first subpixel and a second hole corresponding to the second subpixel;
a first color converting part disposed in the first hole in the first layer; and
a transparent material disposed in the second hole in the first layer,
wherein the first color converting part is configured to output a color of light that corresponds to a color of the first color filter layer.
